(19) United States
(12) Patent Application Publication
(10) Pub. No.: US 2024/0426022 A1
(43) Pub. Date: Dec. 26, 2024

(54) PIEZOELECTRIC EPITAXIALLY GROWN PSEUDOSUBSTRATE, USE AND PROCESS FOR PREPARING SUCH A PSEUDOSUBSTRATE

(71) Applicants: Centre National de la Recherche Scientifique, Paris (FR); Universite de Montpellier, Montpellier (FR); Universitat Autonoma de Barcelona, Barcelona (ES)

(72) Inventors: Adrien CARRETERO, Clapiers (FR); David SANCHEZ FUENTES, Montpellier (FR); Lorenzo GARCIA, Montpellier (FR); Ricardo GARCIA, Clapiers (FR); Samir BOUISRI, Saint Bres (FR); Javier MORAL VICO, Barcelona (ES)

(21) Appl. No.: 18/291,030

(22) PCT Filed: Jul. 21, 2022
(86) PCT No.: PCT/FR2022/051466

§ 371 Date: Jan. 22, 2024

(30) Foreign Application Priority Data
Jul. 22, 2021 (FR) FR2107939

(51) Int. Cl. C30B 29/18; C30B 1/02; H03H 3/02; H03H 9/19

(52) U.S. Cl. CPC C30B 29/18; C30B 1/023; H03H 3/02; H03H 9/19

(57) ABSTRACT

The present invention relates to a piezoelectric, epitaxially grown pseudosubstrate comprising a silicon wafer (100) having two parallel faces, and a thin layer of α-quartz (100) grown epitaxially on one of the faces of said wafer, said thin α-quartz layer (100) exhibiting a uniform crystallization with a mosaicity around the peak (100) of the quartz of between 6° and 1° and a thickness of between 100 nm and 1 μm. The present invention also relates to a process for fabricating such a pseudosubstrate, and to the use thereof for producing piezoelectric membranes.

### ART

The present invention relates in a general way to the production of a piezoelectric epitaxially grown pseudo-substrate comprising a α-quartz layer epitaxially grown on a silicon wafer, the use thereof for making piezoelectric micro electromechanical systems (MEMS), as well as to the method of manufacturing of such a pseudo-substrate.

### PRIOR ART

Piezoelectric materials are at the heart of many daily applications, due to the intrinsic capacity thereof to generate electrical charges under applied mechanical stress or to induce mechanical deformation from an electrical input. Such properties make said materials key elements of the motion sensors and of the resonators present in many wireless network sensors, which are devices apt to autonomously collect and send environmental data. Thereby, in such context, piezoelectric materials can find many military, medical and environmental applications. Today, the monolithic integration of such materials in silicon technology and silicon micromachining, in order to develop cost-effective alternative, higher performance methods, are among the central points of current technology.

Generally, the piezoelectric materials PZT (lead zirconate titanate PbZrTiO₃), ZnO (zinc oxide) and AlN (aluminium nitride) are integrated in the form of thin films on Si substrates for the marketing of chips. On the other hand, quartz devices have hitherto been micromachined from massive crystals^{[1]}. The drawbacks of the former is not being able to reduce the size thereof below a thickness of 10 μm, and of requiring, for most of the applications thereof, the quartz crystals to be bonded to silicon substrates^{[2]}. Such drawbacks represent significant constraints for the microelectronics industry, since thinner monocrystalline quartz wafers are currently in high demand in order to allow the devices to be used with higher working frequencies, as well as for the ability thereof to achieve lower detection levels with a better sensitivity^{[3]}.

α-quartz is a strategic material in Europe, widely used as a piezoelectric material due to the exceptional properties thereof. Indeed, α-quartz has excellent thermal and chemical stability and high mechanical properties, making same one of the best candidates for frequency control devices and acoustic and mass sensor technologies. The scientific publication by Carretero-Genevrier, A. et al. (“Soft—Chemistry-Based Routes to Epitaxial alpha-Quartz Thin Films with Tunable Textures”) in Science 340, 827-831 (2013)^{[4]} describes the direct chemical integration of α-quartz epitaxially grown on silicon substrates (100), on which the international Application WO 2014/016506 [5] is based. Said application teaches in particular how the adaptation of the structure of α-quartz films on silicon substrates was carried out by chemical deposition in solution (dip-coating technique, as is generally referred to by a person skilled in the art), which made it possible to control the texture, the density and the thickness of the films.

However, the thin films of α-quartz obtained by such technology cannot be used for making piezoelectric micro electro-mechanical systems (MEMS). However, there is thus to date no chemical method making it possible to industrialize the integration of thin films based on α-quartz epitaxially grown on silicon, with a single crystalline orientation and perfectly controlled homogeneity.

Therefore, there is considerable interest in developing a technology for fabricating such an α-quartz thin film on a silicon substrate allowing a change of scale, i.e. to integrate α-quartz in the form of a thin epitaxially grown film on surfaces larger than the surfaces permitted by the method of preparing an epitaxially grown alpha-quartz layer on a solid support as taught by the International Application WO2014/016506^{[5]}.

### DESCRIPTION OF THE INVENTION

In order to address the above-mentioned issues, the applicant has developed an epitaxially grown piezo-electric material comprising:
a wafer of monocrystalline semiconductor material having two faces, and
a thin film of α-quartz (100) epitaxially grown on at least one face of the wafer,
characterized in that said wafer of monocrystalline semiconductor material is a silicon (100) wafer, and
in that said thin film of α-quartz (100) has a homogeneous crystallization with a mosaicity around the peak (100) of the quartz comprised between 6° and 1° and a thickness comprised between 100 nm and μ1 m.

The term “epitaxially grown pseudo-substrate” as defined by the present invention refers to a wafer of material manufactured by epitaxial growth (epitaxy) and intended to be used in photonics, microelectronics, spintronics or photovoltaics. In the context of the present invention, the wafer of material is a thin film of α-quartz epitaxially grown on a silicon (100) wafer.

Mosaicity, as defined by the present invention, refers to a measure of the dispersion of the orientations of the crystalline planes: a mosaic crystal is an idealized model of an imperfect crystal, which one imagines as consisting of many small perfect crystals (crystallites) which are, to some extent, randomly misoriented. The crystalline mosaic model goes back to a theoretical analysis of X-ray diffraction by C. G. Darwin ^{[6]}. For the time being, most studies are based on the theory thereof, starting from the hypothesis of a Gaussian distribution of crystallite orientations centred on a reference orientation. Mosaicity is generally considered to be the standard deviation of said distribution.

Since mosaicity is a spreading of the orientations of the plane, the degree of mosaicity of a crystal, as defined by the present invention, is the measure of the misalignment of the domains of matter which compose the crystal. The curves shown in FIG. 2 hereinafter show us that the mid-height width of the tilt curves of quartz (100) decreases with the increase in the molar ratio catalyst:SiO2 (hereinafter denoted by the terms “Sᵣ Molar Ratio” in FIG. 2a) and hence that the mosaicity of the thin film of α-quartz decreases with the increase in the molar concentration (CSᵣ) of the precursor solution used to catalyse the quartz nucleation reaction.

FIG. 1 is a spider diagram which illustrates the main advantages of the piezoelectric epitaxially grown pseudo-substrate according to the invention compared with a material comprising a thin film of α-quartz epitaxially grown on silicon (100) substrates, as taught in the International Application WO2014/016506. More particularly, the figure shows that for equivalent rugosity properties and slightly higher continuity properties of the epitaxially grown α-quartz layer in the case of the pseudo-substrate according to the invention, the scalability (i.e. the capacity to change scale of the pseudo-substrate), the mosaicity and homogeneity of the α-quartz layer being significantly improved. Thereby, the pseudo-substrates epitaxially grown according to the invention comprise a thin film of α-quartz which can be completely homogeneous when epitaxially grown on silicon substrates in the form of disks of 2, 3 or 4 inches in diameter, or even larger (corresponding to diameters of 5.04 cm, 7.62 cm and 10.16 cm, respectively, which are the conventional dimensions of silicon wafers for commercially available electronic devices), which makes same suitable for being used in the production of piezoelectric micro-electro-mechanical systems.

Advantageously, the face on which the thin film of α-quartz is deposited can have a surface area of at least 20 cm² (surface area corresponding approximately to a wafer in the form of a disk with a diameter of 2 inches, i.e. 5.08 cm), and preferentially between 20 cm² and 82 cm² (surface area corresponding approximately to a wafer in the form of a disk with a diameter of 4 inches, i.e. 10.16 cm).

Advantageously, the thickness of said thin film (12) of α-quartz (100) can be a thickness between 200 nm and 1 μm.

According to an advantageous embodiment, the thin film of α-quartz can have a mosaicity comprised between 2.5° and 1.4°.

For such advantageous embodiment, it is advantageous to use, as silicon (100) wafer, an N-doped silicon wafer (in particular doped with phosphorus), having a resistivity on the order of 0.025 Ohm/cm². In such case, the wafer can have a thickness on the order of 100 μm, with polished faces.

A further subject matter of the present invention is a micro-electro-mechanical system in the form of a piezoelectric resonant membrane comprising an epitaxially grown piezoelectric substrate according to the invention.

Finally, a further subject matter of the present invention is a method for manufacturing an epitaxially grown piezoelectric substrate according to the invention, comprising the following steps:
A) a step of preparing composition comprising a solvent and at least one precursor of silica and/or colloidal silica;
B) a step of providing a wafer of monocrystalline semiconductor material having two faces;
C) a step of depositing at least one layer of the composition obtained at the end of step A), the deposition being carried out on at least part of one of the faces of said wafer;
D) a step of heat-treating said wafer thereby coated;
   said method being characterized in that the composition prepared during step
      A comprises a catalyst chosen from the following elements with a degree of oxidation+2, forming the group comprising strontium, barium, calcium, magnesium and beryllium or from the following elements with a degree of oxidation of +1, forming the group consisting of cesium, rubidium, lithium, sodium or potassium, said catalyst being present in a molar ratio catalyst:SiO2 of at least 0.0375 and 0.125; and
in that said wafer of semiconductor material provided during step B) is a wafer of silicon; and
in that step C) of depositing said composition is carried out by spin coating, and
in that said method further comprises, between steps C) and D), an intermediate step C′) of heat pre-treatment at a temperature comprised between 400° C. and 600° C., so as to form, at the end of step C′), a thin film of consolidated amorphous silica;

The method according to the invention makes it possible, by means of carrying out step C of spin coating, to be perfectly suited to the format of silicon wafers in the form of disks (or wafers) used in microelectronics because it is easy to obtain completely homogeneous layers of α-quartz on silicon wafers of 2, 3 and 4 inches (and even larger wafers).

Step A consists in preparing a composition comprising a solvent, at least one precursor of silica and/or of colloidal silica, and a catalyst chosen from strontium, barium, calcium, magnesium and beryllium (with a degree of oxidation+2) or among caesium, rubidium, lithium, sodium or potassium (with a degree of oxidation+1), the catalyst being present in a molar ratio catalyst:SiO2 between 0.0375 and 0.125.

Strontium (in the Sr²⁺ form) will preferentially be used as catalyst.

Catalyst molar ratio:SiO2, as defined by the present invention, refers to the number of moles of catalyst present in the composition prepared during step A divided by the number of moles of precursor of silica or of colloidal silica.

A catalyst molar ratio: SIO 2 guarantees that the thin film of α-quartz (100) formed at the end of step D of the method according to the invention exhibits a homogeneous crystallization with a mosaicity around the peak (100) of α-quartz, comprised between 6° and 1°.

Preferentially, in the composition prepared during step A, an amount of catalyst can be used such that the molar ratio catalyst:SiO2 is between 0.075 and 0.125 and is preferentially equal to 0.1.

A molar ratio catalyst:SiO2 between 0.075 and 0.125 guarantees that the thin film of α-quartz (100) formed at the end of step D of the method according to the invention presents a homogeneous crystallization with a mosaicity around the peak (100) of α-quartz, comprised between 2.5° and 1.4°,

As silica precursor, it is advantageously possible to use in the method according to the invention a precursor chosen from methyltrimethoxysilane (MTMS), tetraethoxysilane (TEOS), methyltriethoxysilane (MTES), dimethyldimethoxysilane, and mixtures thereof.

Preferentially, tetraethoxysilane (generally denoted by the acronym TEOS) will be used as precursor.

Preferentially, the composition prepared during step A can further comprise a non-ionic surfactant, which is preferentially polyoxyethylene cetyl ether (for example same sold by SIGMA ALDRICH under the trademark Brij® 58). The addition of a non-ionic surfactant to the composition of step A of the method according to the invention leads to obtaining a stability of the composition over several weeks, or even several months, and to reach a higher molar ratio catalyst:SiO2 by increasing the solubility of the strontium salt.

Advantageously, the composition prepared during step A can further comprise one or a plurality of additives such as pH control agents (e.g. HCl), structuring or modifying agents or else porosity-promoting agents such as polymers, quaternary ammoniums and urea.

Finally, as solvent used in the composition prepared during step A of the method according to the invention, water, alcohol (in particular ethanol) or an aqueous-alcoholic mixture can be typically used.

During step B of providing a substrate, a wafer of monocrystalline semiconductor material having two parallel faces, as defined above, is used. Within the framework of the present invention, a silicon (100) wafer is used.

Thereby, advantageously, it is possible to use a wafer the faces (and in particular the face on which the α quartz film is deposited) of which have a surface area of at least 20 cm² (surface area corresponding approximately to the surface area of a wafer in the form of a disk with a diameter of 2 inches, i.e. 5.08 cm) and preferentially between 20 cm² and 82 cm² (surface area corresponding approximately to the surface area of a wafer in the shape of a disk with a diameter of 4 inches, i.e. 10.16 cm)

Preferentially, it is possible to use an N-doped silicon wafer having a resistivity on the order of 0.025 Ohm/cm².

During step C of depositing at least one layer of the composition prepared during step A of the method according to the invention, the composition is deposited by spin coating, as referred to by a person skilled in the art) on at least part of one face of the wafer. Such step is necessarily followed by an intermediate step C′) of heat pre-treatment at a temperature comprised between 400° C. and 600° C., so as to form at the end of the step, at least one thin film of consolidated amorphous silica, which forms a precursor thin film of the α-quartz (100) thin film. The catalyst is present within the amorphous silica matrix: same acts as a crystal lattice modifier (devitrifying agent) and lowers the melting point of the silica and makes possible the crystallization of the silica at low temperature.

Advantageously, steps C and C′ can be repeated successively one or more times.

According to an advantageous embodiment of the present invention, step C can be carried out as follows, in two phases:
A first phase of dynamic dispensing of the composition of step A by centrifugation at a speed of 100-500 rpm, and preferentially at 300 rpm, for 5 to 10 seconds; followed by
a second phase of formation of the α-quartz (100) thin film by centrifugation at a speed of 500-6000 rpm, for 10 to 40 seconds.

The first dispensing phase serves to facilitate the dispensing of the composition over the entire wafer, while the second dispensing phase makes it possible to form and control the thickness of the deposited layer(s), as illustrated in FIG. 3

Within the framework of such advantageous embodiment, step C can comprise a delay time between the two dispensing phases which is between 0 and 15 s.

Within the framework of such advantageous embodiment, step C′ can preferentially be carried out at a temperature comprised between 450° C. and 600° C., for 4 minutes.

Within the framework of such advantageous embodiment, steps C and C′ can be repeated 4 times, successively.

Steps C and C′ are followed by a step D of heat treatment of the wafer thereby coated with at least one precursor thin film of the α-quartz (100) thin film.

Advantageously, the heat treatment step D) can be carried out at a temperature comprised between 800° C. and 1200° C., and preferentially at 980° C. for a length of time of 5 hours, in a tubular furnace with an air flow of 12 I/minute.

At the end of such step, the furnace is switched off and let cool down naturally to 25° C.

Such a method benefits from the advantages of soft and sol-gel chemistry, and from method of deposition using spin coating. More particularly, deposition technology is the technique best suited to the formats of supports generally used in microelectronics: in other words, such a technology makes it easy to obtain completely homogeneous layers of α-quartz on substrates or silicon wafers with diameters of 5.08 cm, 7.62 cm and 10.16 cm (corresponding to diameters of 2, 3 and 4 inches, respectively), or even larger diameters (as shown in FIG. 6). Furthermore, the amount of solution per substrate required to obtain a quartz layer is minimal: the preparation of only 10 ml of solution can be used for the deposition of at least 10 wafers with a diameter of 10.16 cm (or 1 ml per substrate), which significantly saves the costs of the chemical components used in the manufacturing method.

Such properties of scalability, homogeneity and low cost, relating to the simplicity of the method, make same perfectly suited to large-scale industrialization.

Other advantages and features of the present invention will result from the following description, given as an example, but not limited to, and with reference to the enclosed figures and the examples.

### BRIEF DESCRIPTION OF THE FIGURES

The following examples illustrate the invention, with reference to the figures commented on hereinabove, without however limiting the scope of the figures:

FIG. 1 is a spider diagram that shows a detailed analysis of a plurality of important features of the integration of α-quartz thin films by dip-coating and spin coating techniques, as well as the point-by-point comparison thereof according to the importance given to each feature.

FIG. 2 illustrates how the catalyst concentration in the composition formed during step A of the method according to the invention makes it possible to control the mosaicity of the α-quartz layers made on 2-inch silicon substrates with a strontium catalyst (cf. example 1):

FIG. 2a shows the decrease in mosaicity when the molar ratio catalyst:SiO2 in the composition of step A increases;

FIG. 2b shows the increase in crystallinity of α-quartz layers when the molar ratio catalyst:SiO2 in the composition of step A increases;

FIG. 2c comprises maps of the degree of mosaicity showing the homogeneity of α-quartz layers made with different molar ratios catalyst:SiO2 (denoted by R_{Sr}).

FIG. 3 shows the characterization of α-quartz layers produced at different speeds of spin coating during step C of the method according to the invention (cf. example 2):

FIG. 3a shows the control of the thickness of the α-quartz layer by the rotational speed of the spin coating (second phase);

FIG. 3b shows the variation of the mosaicity of the α-quartz peak (100) as a function of the speed of rotation.

FIG. 3c comprises different SEMFEG images showing the thicknesses of the sections of the layers produced at different speeds;

FIG. 3d comprises different maps of the degree of mosaicity showing the homogeneity of α-quartz layers produced at different speeds.

FIG. 4 shows the influence of the delay time between the phase of dispensing of the solution over the substrate and the final phase of spin coating (step C of the method according to the invention) on the thin film of α-quartz (cf. example 3):

FIG. 4a shows the variation of the mosaicity of the peak (100) of the α-quartz as a function of the delay time;

FIG. 4b shows the variation in the intensity of the peak (100) of the α-quartz as a function of the delay time;

FIG. 4c comprises different SEMFEG Images showing the change of the thickness of α-quartz thin films produced at different delay times;

FIG. 4d comprises different maps of the degree of mosaicity of the peak (100) of the α-quartz, showing the change of the mosaicity as well as the homogeneity of the α-quartz layers as a function of the delay time.

FIG. 5 shows the influence of the number of deposition layers on the characterization of the pseudo-substrate obtained by the method according to the invention (cf. example 4):

FIG. 5a shows the results of θ-2θ diffraction for different numbers of layers deposited with an inset (“Rocking curve” of the same samples);

FIG. 5b is a representation of the intensity of the peak (100) of the α-quartz and of the estimated thickness of the final thin film of α-quartz as a function of the number of layers deposited, with one inset (the representation of the degree of mosaicity around the peak (100) of the α-quartz shows the invariance thereof at the number of layers);

FIG. 5c is a comparison, by SEMFEG imaging, of the thickness of the final α-quartz thin film of two samples obtained by 4 coatings (710 nm thick) and 1 deposition (180 nm thick);

d) FIG. 5d comprises the different maps of the intensity and of the degree of mosaicity of the peak (100) of the α-quartz, showing the homogeneity of α-quartz layers with different numbers of coatings.

FIG. 6 illustrates the scalability of the manufacturing of piezoelectric α-quartz layers epitaxially grown on silicon:

FIG. 6a shows images of different sizes of crystallized silicon wafers, which are used in the microelectronics industry;

FIG. 6b comprises different maps of the degree of mosaicity of the samples showing the constancy of the homogeneity of the α-quartz layer for the different sizes of silicon wafers used.

FIG. 7 illustrates the characterization of a α-quartz layer made under “optimal” conditions on a Si wafer with a diameter of 2 inches:

FIG. 7a comprises an optical image showing the continuity of the α-quartz thin film (on the right) and an SEM image showing the thickness of the crystallized α-quartz layer (on the left).

FIG. 7b is an AFM image showing the texture and the rugosity of the thin film of α-quartz,

FIG. 7c shows the results of 6-28 diffraction, with an inset: Mapping of the degree of mosaicity of the wafer around the peak (100).

FIG. 7d is a pole figure showing the epitaxy between the Si wafer and the layer of α-quartz.

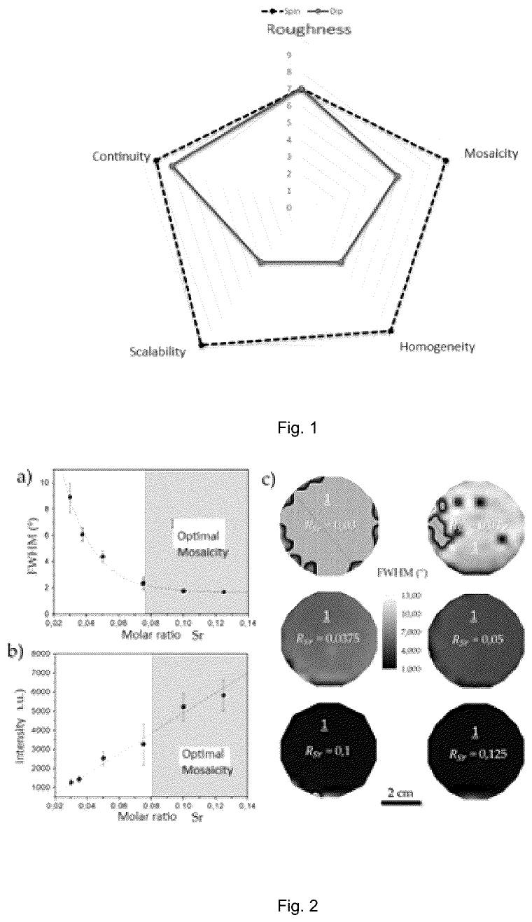

FIG. 1 was described in the preceding descriptive part, whereas FIGS. 2 to 7 are described in greater detail along the following examples, which illustrate the invention without limiting the scope thereof.

### EXAMPLES

The nature of the products used for the manufacturing of piezoelectric epitaxially grown pseudo-substrates according to the invention, the method used for the manufacturing and the optimization of operation conditions thereof, as well as the methods for characterizing the α-quartz thin film are discussed in detail hereinafter.

### Products, Raw Materials:

N-doped silicon wafers: standard disk-shaped wafers with diameters of 2, 3, and 4 inches (i.e. 5.08 cm, 7.62 cm and 10.16 cm, respectively) are used,
98% tetraethoxyorthosilane (TEOS), sold by Sigma-Aldrich,
ethanol (EtOH),
ultra-pure H₂O.
hydrochloric acid (HCl) 37%, sold by Sigma-Aldrich,
strontium chloride (SrCl₂·6H₂O), sold by Sigma-Aldrich,
Polyethylene glycol hexadecyl ether sold by Sigma-Aldrich under the trade name Brij-58®,

### Instruments and Tests for Structural and Microstructural Characterization

A complete physical and chemical characterization was performed using: —an atomic force microscope (AFM), marketed by Veeco under the trade name MULTIMODE, for determining the rugosity and the appearance of the layer of α-quartz (100);
a Scanning Electron Microscope-Field Emission (SEM-FEG) marketed by Hitachi under the trade name SU90, for determining the thickness of the layer of α-quartz (100);
a diffractometer marketed under the trade name GADDS D8 in a Bruker assembly, copper irradiation 1.54056 Å, for determining the epitaxy, the mosaicity and the crystalline homogeneity.

Example 1: method of manufacturing an epitaxially grown piezoelectric pseudo-substrate according to the invention: optimization, during step A of the method according to the invention, of the molar ratio catalyst:SiO₂.

A plurality of precursor solutions comprising the following compounds were prepared according to step A of the method according to the invention: TEOS, Brij-58, HCl, EtOH, SrCl₂:1:0.43:0.7:25:0.1 by changing the molar ratio SrCl₂:TEOS from 0.035 to 0.125, increasing the amount of strontium (the other concentrations remain unchanged). Above a molar ratio of 0.125, a problem of solubility and hence of stability of the precursor solutions was observed.

A standard silicon wafer with a diameter of 2 inches (7.62 cm) and having a thickness of 100 μm, with a conductivity of 0.025 Ω/cm, was used.

Then, according to step C of the method according to the invention, a precursor composition prepared during step A was deposited on one of the faces 20 of the wafer 2. The deposition was carried out by spin coating at a temperature of 20° C. and 40% relative humidity, under the following conditions:
i. dynamic dispensing of 1 ml solution at 300 rpm for 5 s;
ii. then, a final rotation of 2000 rpm for 30 seconds.

According to step C′ of the method according to the invention, the composition layer thus deposited was consolidated by a heat treatment at 450° C., in order to obtain a thin film of consolidated amorphous silica, which formed a precursor thin film of the thin film of α-quartz (100).

There was only one repetition of steps C and C′.

The final heat treatment during step D was then carried out on the silicon wafer thus coated with amorphous silica, at a temperature of 980° C. for 5 hours, in a tubular furnace with an air flow of 12 I/minute. The furnace was then switched off and allowed to cool down naturally to 25° C.

FIG. 2 shows different maps on the mosaicity of α-quartz layers with 150 uniformly distributed points, the layers having been obtained from the spin deposition of the different compositions of step A, i.e. with different molar ratios SrCl₂:TEOS.

The maps (FIG. 2C) show, statistically, the crystallinity and the homogeneity of the layers:
from a molar ratio SrCl₂:TEOS of 0.035, the amorphous silica layer began to crystallize into α-quartz, and
it was from a molar ratio SrCl₂:TEOS of 0.075 on, that the α-quartz layer became perfectly homogeneous throughout the substrate, going hand-in-hand with a decrease in mosaicity.

Specifically, FIG. 2 shows that a molar ratio SrCl₂:TEOS comprised between 0.075 and 0.125 guaranteed a homogeneous crystallization of the α-quartz layer with a mosaicity between 2.5° and 1.4°, making it possible to make use of the piezoelectric properties of the layer

Example 2: method for manufacturing an epitaxially grown piezoelectric pseudo-substrate according to the invention: optimization, during step C of the method according to the invention, of the speed of spin coating.

A precursor solution having the following initial composition (in moles) was prepared according to step A of the method according to the invention: TEOS:Brij-58:HCl:EtOH:SrCl₂:1:0.43:0.7:25:0.1.

A silicon wafer of 2 inches and having a thickness of 100 μm, with a conductivity of 0.025 Ω/cm, was used.

Then, according to step C of the method according to the invention, the precursor composition prepared during step A was deposited on one of the faces 20 of the wafer 2. The deposition was carried out by spin coating at a temperature of 20° C. and 40% relative humidity, under the following conditions:
i. dynamic dispensing of 1 ml solution at 300 rpm for 5 s;
ii. then, a final rotation for 30 seconds, which was changed from 1000 rpm to 3500 rpm (6 speed of coatings being tested: 1000 rpm; 1500 rpm; 2000 rpm; 2500 rpm; 3000 rpm; 2500 rpm).

According to step C′ of the method according to the invention, the composition layer thus deposited was consolidated by a heat treatment at 450° C., in order to obtain a thin film of consolidated amorphous silica, which formed a precursor thin film of the thin film of α-quartz (100). There was only one repetition of steps C and C′.

The final heat treatment during step D was then carried out on the silicon wafer thus coated with amorphous silica, at a temperature of 980° C. for 5 hours, in a tubular furnace with an air flow of 12 I/minute. The furnace was then switched off and allowed to cool down naturally to 25° C.

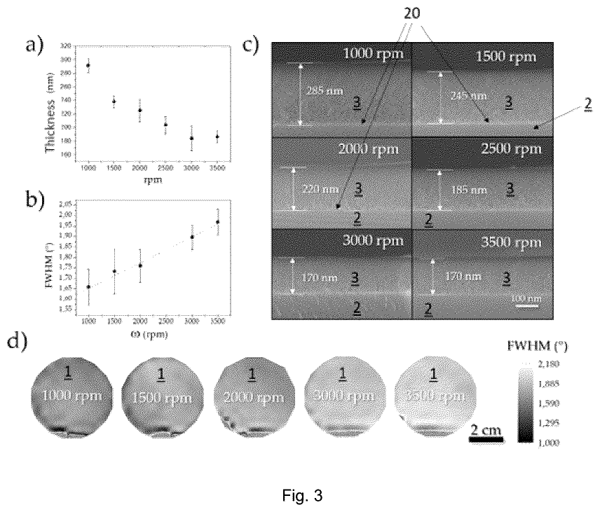

At the end of step D of the method according to the invention, a wafer of silicon (100) was obtained, covered with a layer of α-quartz, the thickness of which, as characterized by microscopy, was comprised between 300 nm and 170 nm. The characterization of the layer is illustrated in FIGS. 3c and 3d.

FIG. 3 shows that the speed of rotation during the second spin coating phase of step C made it possible to control the thickness of the α-quartz layer deposited: a slight increase in the degree of mosaicity of the final α-quartz layers was observed when the speed of coating of the second phase increased (FIG. 3d). Specifically, a deposition at 300 rpm during the first phase of step C, followed by spin coating between 1000 rpm and 3500 rpm for 30 seconds during the second step guaranteed homogeneous layers of α-quartz, the thicknesses of which could be comprised between 170 nm and 300 nm.

Example 3: method of manufacturinq of an epitaxially grown piezoelectric pseudo-substrate according to the invention: optimization of the delay time between the phase of dispensing the solution over the substrate and the final phase of spin coating (step C of the method according to the invention) on the thin film of α-quartz.

A precursor solution was prepared according to the step A of the method according to the invention, having the following initial composition (in moles): TEOS:Brij-58:HCl:EtOH:SrCl2:1:0.43:0.7:25:0.1.

A silicon wafer of 2 inches and having a thickness of 100 μm, with a conductivity of 0.025 Ω/cm, was used.

Then, according to step C of the method according to the invention, the precursor composition prepared during step A was deposited on one of the faces 20 of the wafer 2. The deposition was carried out by spin coating at a temperature of 20° C. and 40% relative humidity, under the following conditions:
i. A dynamic dispensing of 1 ml solution at 300 rpm for 5 s;
ii. wait for a period of time ranging from 0 to 15 s;
iii. then, a final rotation of 2000 rpm for 30 seconds.

According to step C′ of the method according to the invention, the composition layer thus deposited was consolidated by a heat treatment at 450° C., in order to obtain a thin film of consolidated amorphous silica, which formed a precursor thin film of the thin film of α-quartz (100). There was only one repetition of steps C and C′.

The final heat treatment during step D was then carried out on the silicon wafer thus coated with amorphous silica, at a temperature of 980° C. for 5 hours, in a tubular furnace with an air flow of 12 I/minute. The furnace was then switched off and allowed to cool down naturally to 25° C.

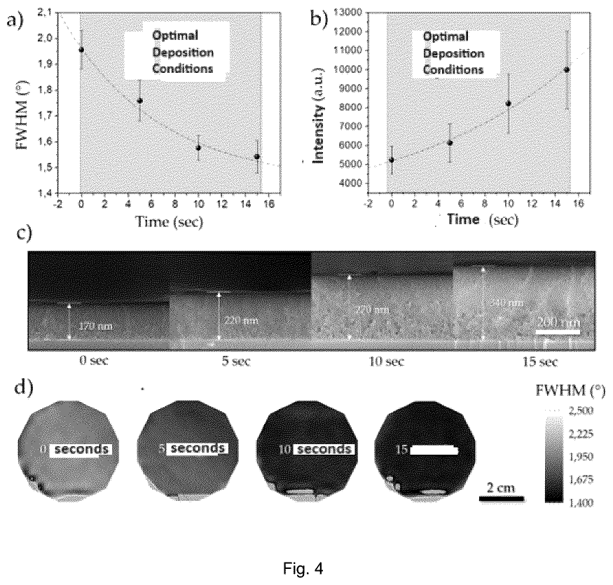

At the end of step D of the method according to the invention, a silicon (100) [wafer] was obtained covered with a layer of α-quartz which had been characterized as illustrated in FIGS. 4C and 4d.

FIG. 4 shows that, for a speed of coating (second phase of step C) of 2000 rpm, the increase in the delay time makes it possible to increase the thickness of the thin α-quartz layer, while maintaining the homogeneity thereof: there is a change from 170 nm when there is no delay time to 300 nm for a delay time of 15 s (FIG. 4c), with a mosaicity around the peak (100) of the quartz which is homogeneous throughout the substrate (FIG. 4d).

Example 4 method of manufacturing an epitaxially grown piezoelectric pseudo-substrate according to the invention: optimization of the number of repetitions of steps C and C′ (number of layers deposited).

A precursor solution was prepared according to the step A of the method according to the invention, having the following initial composition (in moles): TEOS:Brij-58:HCl:EtOH:SrCl2:1:0.3:0.7:25:0.1.

A silicon wafer of 2 inches and having a thickness of 100 μm, with a conductivity of 0.025 Ω/cm, was used.

Then, according to step C of the method according to the invention, the precursor composition prepared during step A was deposited on one of the faces 20 of the wafer 2. The deposition was carried out by spin coating at a temperature of 20° C. and 40% relative humidity, under the following conditions:
i. dynamic dispensing of 1 ml solution at 300 rpm for 5 s;
ii. then, a final rotation of 2000 rpm for 30 seconds.

According to step C′ of the method according to the invention, the composition layer thus deposited was consolidated by a heat treatment at 450° C., in order to obtain a thin film of consolidated amorphous silica, which formed a precursor thin film of the thin film of α-quartz (100).

The succession of the steps C and C′ could be repeated up to 4 times.

The final heat treatment during step D was then carried out on the silicon wafer thus coated with amorphous silica, at a temperature of 980° C. for 5 hours, in a tubular furnace with an air flow of 12 I/minute. The furnace was then switched off and allowed to cool down naturally to 25° C.

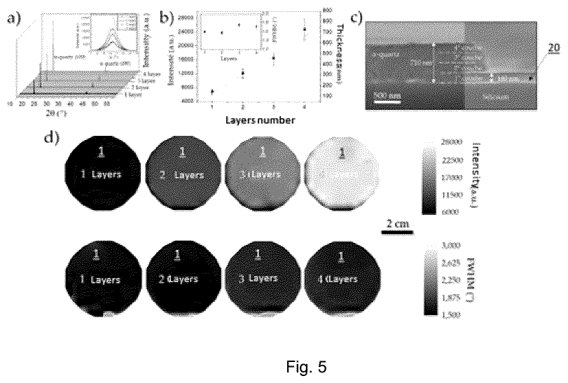

At the end of step D of the method according to the invention, a silicon (100) wafer was obtained, covered with a layer of α-quartz, the thickness of which varied from 180 nm (a single repetition of steps C and C′) to 710 nm (4 repetitions of steps C and C′), as illustrated in FIG. 5c.

The intensity of the peak (100) of the final quartz layer and the thickness thereof increased linearly for each repetition carried out (cf. FIG. 5a), keeping the mosaicity of the layer constant (cf. FIG. 5b). A mosaicity was also observed around the peak (100) of the quartz layer, which was homogeneous throughout the substrate (cf. FIG. 5d).

Example 5: method of manufacturing an epitaxially grown piezoelectric pseudo-substrate according to the invention: optimization of the size of the silicon wafers used (scalability tests).

A precursor solution was prepared according to the step A of the method according to the invention, having the following initial composition (in moles): TEOS:Brij-58:HCl:EtOH:SrCl2:1:0.3:0.7:25:0.1.

Silicon wafers with diameters of 2, 3 and 4 inches (corresponding to diameters of 5.08 cm, 7.62 cm and 10.16 cm, respectively) and a thickness of 100 μm, with a conductivity of 0.025 Ω/cm, were used.

Then, according to step C of the method according to the invention, the precursor composition prepared during step A was deposited on one of the faces 20 of the wafer 2. The deposition was carried out by spin coating at a temperature of 20° C. and 40% relative humidity, under the following conditions:
i. dynamic dispensing of 1 ml solution at 300 rpm for 5 s;
ii. then, a final rotation of 2000 rpm for 30 seconds.

According to step C′ of the method according to the invention, the composition layer thus deposited was consolidated by a heat treatment at 450° C., in order to obtain a thin film of consolidated amorphous silica, which formed a precursor thin film of the thin film of α-quartz (100).

The succession of the steps C and C′ was carried out once for each “wafer”.

The final heat treatment during step D was then carried out on the silicon wafer thus coated with amorphous silica, at a temperature of 980° C. for 5 hours, in a tubular furnace with an air flow of 12 I/minute. The furnace was then switched off and allowed to cool down naturally to 25° C.

At the end of step D of the method according to the invention, a wafer of silicon (100), was obtained covered with a layer of α-quartz.

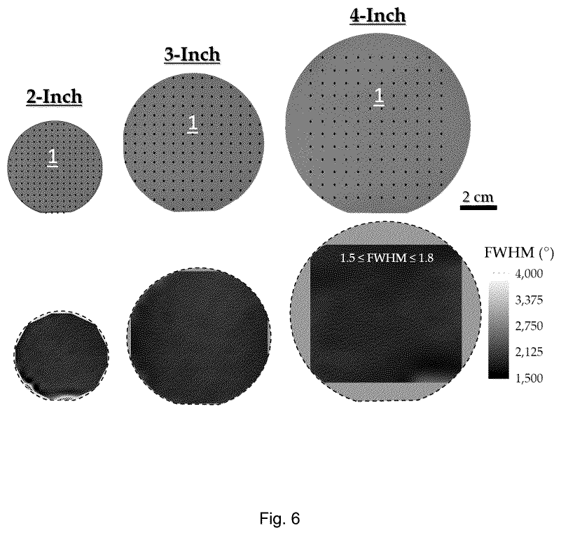

FIG. 6 shows that the method according to the invention, and more particularly the spin coating of step C, are perfectly suited to the formats of the substrates usually used in microelectronics, i.e. Si wafers with diameters of 2 inches, 3 inches and 4 inches (cf. FIG. 6a). In other words, the method according to the invention makes it possible to easily obtain totally homogeneous α-quartz layers of α-quartz on silicon substrates of 2, 3 and 4. FIG. 6b shows the conservation of the mosaicity and of the crystallinity with the size of the silicon wafer. Furthermore, the amount of solution per substrate required to obtain a α-quartz layer is minimal: 10 ml of composition (prepared during step A of the method according to the invention) were used for the deposition of at least 10 substrates of 4 inches (i.e. 1 ml of composition per 4-inch wafer), which is a huge saving on the cost of chemical components.

The properties of scalability, homogeneity and low cost related to the simplicity of the method, make the method perfectly oriented towards the marketing of quartz-silicon substrates and/or devices made from such substrates.

Example 6 Production of an example of a piezoelectric epitaxially grown pseudo-substrate according to the invention.

A precursor solution was prepared according to the step A of the method according to the invention, having the following initial composition (in moles): TEOS:Brij-58:HCl:EtOH:SrCl2:1:0.3:0.7:25:0.1.

A silicon wafer of 3 inches and having a thickness of 100 μm, with a conductivity of 0.025 Ω/cm, was used.

Then, according to step C of the method according to the invention, the precursor composition prepared during step A was deposited on one of the faces 20 of the wafer 2. The deposition was carried out by spin coating at a temperature of 20° C. and 40% relative humidity, under the following conditions:
i. dynamic dispensing of 1 ml solution at 300 rpm for 5 s;
ii. then, a final rotation of 2000 rpm for 30 seconds.

According to step C′ of the method according to the invention, the composition layer thus deposited was consolidated by a heat treatment at 450° C., in order to obtain a thin film of consolidated amorphous silica, which formed a precursor thin film of the thin film of α-quartz (100).

The succession of the steps C and C′ was repeated 4 times.

The final heat treatment during step D was then carried out on the silicon wafer thus coated with amorphous silica, at a temperature of 980° C. for 5 hours, in a tubular furnace with an air flow of 12 I/minute. The furnace was then switched off and allowed to cool down naturally to 25° C.

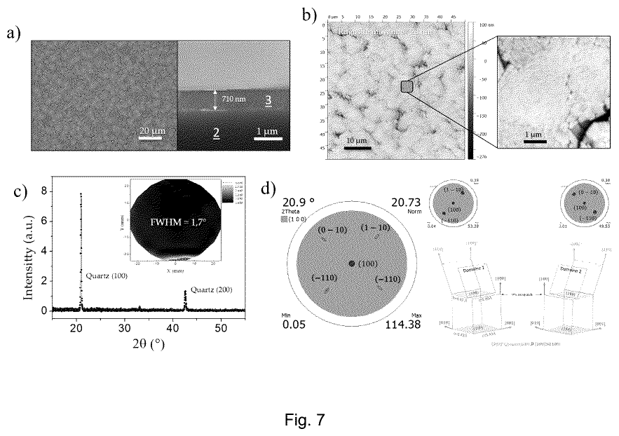

At the end of step D of the method according to the invention, a wafer of silicon (100) was obtained, covered with a layer of α-quartz which had been characterized as follows (cf. FIG. 7):
FIG. 7a (on the right) shows that the thin film of α-quartz thereby obtained consisted of crystalline domains of α-quartz percolated by forming a homogeneous and continuous mat;
FIG. 7a (on the left) shows the section of the α-quartz layer, which had a thickness of 710 nm;
FIG. 7b (AFM image) shows the texture and rugosity of the surface of the layer with an average rugosity of 10 nm, measured over a surface area of 50×50 μm;
FIG. 7c shows that the crystallized layer was indeed a monocrystalline layer of α-quartz. The map shows a mosaicity of 1.7° that is homogeneous throughout the Si wafer, for the peak (100) of the α-quartz. FIG. 7d shows the results of the study of epitaxy by XRD, and more particularly an epitaxy relation of the layer of quartz (100) on the substrate of silicon (100) throughout the polar figure around the reflection (100)=20.9°. FIG. 7d also shows the presence of two quartz domains perpendicular to each other. The two domains, which had an identical epitaxy relation with the silicon substrate ([210] α-quartz (100)//[100]Si (100), are permitted by the cubic symmetry of the silicon substrate. Finally, FIG. 7d shows a model of 3D representation of the orientation and of the relation of two crystal domains of the dense layer of quartz epitaxially grown on silicon.
FIG. 7d also shows the existence of two perpendicular crystal domains of quartz with the same epitaxy relation with silicon. The existence of the two crystalline domains of the quartz layer is possible due to the cubic symmetry of the silicon substrate.

### LIST OF REFERENCES

1. J. S. Danel & G. Delapierre. Quartz: a material for microdevices. Journal of Micromechanics and Microengineering 1, 187 (1991).
2. B. Imbert et al. Thin film quartz layer reported on silicon. in 1-4 (2011). doi:10.1109/FCS.2011.5977829.
3. Brinker, C. J. & Clem, P. G. Quartz on Silicon. Science 340, 818-819 (2013).
4. Carretero-Genevrier, A. et al. Soft-Chemistry-Based Routes to Epitaxial alpha-Quartz Thin Films with Tunable Textures. Science 340, 827-831 (2013).
5. C Boissiere, A Carretero-Genevrier, M Gich, D Grosso, C Sanchez: “Preparation of an epitaxial alpha quartz layer on a solid support, material obtained and applications”, WO20140165 or EP2875172.
6. C. G. Darwin: The reflection of X-rays from imperfect crystals. Philos. Mag. 43, 809-829. 1922.

1. An epitaxially grown piezoelectric pseudo-substrate comprising:
a wafer of monocrystalline semiconductor material having two faces, and
a thin film of α-quartz epitaxially grown on at least one of the faces of said wafer,
wherein said wafer of monocrystalline semiconductor material is a silicon wafer, and
wherein said thin film of α-quartz has a homogeneous crystallization with a mosaicity around the peak of the quartz, comprised between 6° and 1° and a thickness comprised between 100 nm and 1 μm.

2. The epitaxially grown piezoelectric pseudo-substrate according to claim 1, wherein said faces have a surface area of at least 20 cm² or between 20 cm² and 82 cm².

3. The epitaxially grown piezoelectric pseudo-substrate according to claim 1, wherein said thin film of α-quartz has a thickness comprised between 200 nm and 1 μm.

4. The epitaxially grown piezoelectric pseudo-substrate according to claim 1, wherein said thin film of α-quartz exhibits homogeneous crystallization with a mosaicity between 2.5° and 1.4°.

5. The epitaxially grown piezoelectric pseudo-substrate according to claim 3, wherein said wafer is made of N-doped silicon having a resistivity of 0.025 Ohm/cm².

6. The epitaxially grown piezoelectric pseudo-substrate according to claim 5, wherein said wafer has a thickness of 100 μm and the faces thereof are polished.

7. A micro electro-mechanical system in the form of a resonant membrane comprising an epitaxially grown piezoelectric pseudo-substrate according to claim 1.

8. A method of manufacturing an epitaxially grown piezoelectric pseudo-substrate as defined according to claim 1, comprising the steps of:
A) preparing a composition comprising a solvent and at least one precursor of silica and/or colloidal silica;
B) providing a wafer of monocrystalline semiconductor material having two faces;
C) depositing at least one layer of the composition obtained at the end of step A), the deposition being carried out on at least part of one of the faces of said wafer; and
D) heat treating said wafer thereby coating the wafer;
wherein the composition prepared during step A) comprises a catalyst selected from; the following elements with a degree of oxidation +2; strontium, barium, calcium, magnesium or beryllium or from the following elements with a degree of oxidation of +1; cesium, rubidium, lithium, sodium or potassium, wherein said catalyst being present in a molar ratio catalyst:SiO2 between 0.0375 and 0.125; and
wherein said wafer provided during step B) is a wafer of silicon; and
wherein step C) is carried out by spin coating, and
wherein said method further comprises, between steps C) and D), an intermediate step C′) of heat pre-treatment at a temperature between 400° C. and 600° C., so as to form, at the end of step C′) a thin film of consolidated amorphous silica.

9. The method according to claim 8, wherein the composition prepared during step A) comprises a precursor selected from the group consisting of methyltrimethoxysilane (MTMS), tetraethoxysilane (TEOS), methyltriethoxysilane (MTES), dimethyldimethoxysilane, and mixtures thereof.

10. The method according to claim 8, wherein the composition prepared during step A) further comprises a non-ionic surfactant or is polyoxyethylene cetyl ethers.

11. The method according to claim 8, wherein the catalyst of the composition prepared during step A) is present in a molar ratio catalyst:SiO2 between 0.075 and 0.125 or is 0.1.

12. The method according to claim 8, wherein said faces of the wafer have a surface area of at least 20 cm² or between 20 cm² and 82 cm².

13. The method according to claim 8, wherein said wafer of N-doped silicon and has a resistivity of 0.025 Ohm/cm².

14. The method according to claim 8, wherein said steps C) and C′) are repeated successively one or more times.

15. The method according to claim 8, wherein step C) comprises:
a first phase of dynamic dispensing of the composition of step A) by centrifugation at a speed of 100 rpm, for 5 to 10 seconds; followed by
a second phase of formation of the thin film of α-quartz by centrifugation at a speed of 500 rpm, for 10 to 40 seconds.

16. The method according to claim 15, wherein step C) comprises a delay time between the two dispensing phases between 0 and 15 s.

17. The method according to claim 15, wherein step C′) is carried out at a temperature between 450° C. and 600° C., for 4 minutes.

18. The method according to claim 15, wherein steps C) and C′) are repeated 4 times, successively.

19. The method according to claim 8, wherein the heat treatment step D) is carried out at a temperature between 800° C. and 1200° C.

20. The method according to claim 19, wherein the heat treatment step D) is carried out at 980° C. for a length of time of 5 hours in a tubular furnace with an air flow of 121/minute.
